(19) United States
(12) Patent Application Publication
(10) Pub. No.: US 2008/0036098 A1
(43) Pub. Date: Feb. 14, 2008

(54) CONFIGURABLE UNIVERSAL INTERCONNECT DEVICE

(75) Inventors: Julius A. Kovats, Manitou Springs, CO (US); Kenneth M. Jackson, Colorado Springs, CO (US)

Correspondence Address: SCHNECK & SCHNECK, P.O. BOX 2-E, SAN JOSE, CA, 95109-0005, US

(73) Assignee: ATMEL CORPORATION, San Jose, CA (US)

(21) Appl. No.: 11/424,159

(22) Filed: Jun. 14, 2006

(51) Int. Cl. H01L 23/48; H01L 23/52; H01L 29/40

(52) U.S. Cl. 257/780

(57) ABSTRACT

A universal interconnect device for mounting and interconnecting a semiconductor integrated circuit die in preparation for mounting to another substrate such as a printed circuit board. The device consists of a laminate substrate having a first surface upon which the integrated circuit die may be mounted. Underlying and surrounding the die mount area is a plurality of substantially concentric electrically-conductive paths. Each of the plurality of paths is electrically isolated from each other and at least one of the plurality of electrically-conductive paths is located near an outer periphery of the laminate substrate. A plurality of vias traverse the laminate substrate a plurality of bonding features is mounted on a second surface of the substrate. Each of the bonding features is electrically isolated both from one another and from the plurality of paths but is electrically connectable to one or more of the paths through the plurality of vias.

### TECHNICAL FIELD

The present invention, is related to an interconnect device for mounting an integrated circuit die, and more specifically to an interconnect for mounting the integrated circuit die in a electrically-configurable matrix or grid array form.

### BACKGROUND ART

The continuous increase in performance of integrated circuits is having a proportionate increase in demand for integrated circuit packages that dissipate heat more efficiently, operate under higher clock frequencies, and produce smaller footprints while meeting increased reliability requirements. There are a number of packaging technologies that offer some of these properties, but fail to meet others. Multi-layer ceramic and deposited thin film ball grid arrays (BGAs) are among some of the high performance solutions commonly available today. Unfortunately, these solutions tend to be expensive, and therefore fail to meet the highly competitive cost structure associated with high volume packaging operations. As such, the high cost of packaging materials and package manufacturing limit their use in cost sensitive high performance products. Also, the lead time and expense required to create a BGA package limits a quick turn time for samples and prototyping runs.

Of the various types of BGA packaging, ceramic substrate packaging is expensive and has proven to limit the performance of the overall package. Plastic substrate BGA packaging has become commonplace and is frequently used in high volume BGA package fabrication. However, if the number of integrated circuit pins is high, that is in excess of 350 pins, or if the pins are on a small package, resulting in a solder ball pitch of less than 1.27 mm, the plastic BGA structure becomes complicated and expensive. The complexity and expense result from the multi-layer structure used to create the plastic BGA package.

With reference to FIG. 1, a prior art “cavity down” BGA package 100 includes a multi-layer printed circuit board (PCB) substrate and a metal heat spreader 101. The cavity 102 is defined by PCB interconnect metal layers 103, 105, 107, which are patterned over a plurality of dielectric layers 109. The multiple layer PCB is formed, by alternating the interconnect metal layers 103, 105, 107 with the plurality of dielectric layers 109. Bonding shelves 111 are defined as part of each of the first two interconnect metal layers 103, 105. The bond shelves 111 are used for electrically connecting lead wires 113. The wire leads 113 electrically interconnect the BGA package 100 to a semiconductor integrated circuit die 115. (Wire bonding techniques used to electrically connect the wire leads 113 to the bonding shelves 111 are regarded as having limited use in more advanced packaging approaches, partly because wire bonds require greater pitch than is available in many state of the art packages.) The integrated circuit die 115 is attached to the heat spreader 101 with a die attach epoxy 117.

A plurality of vias 119 are typically used to complete electrical interconnections between the interconnect metal layers 103, 105, 107. In typical BGA designs implementing PCB technology (where the minimum metal trace width is about 100 μm), at least four metal layers are needed to interconnect about five rows of solder balls 121, and even more metal layers are needed when power and ground planes are required. Further, the multiple metal layers required to complete complex circuit routing tends to increase the number of metal traces and via interconnects and, consequently, overall cost. Additionally, each integrated circuit design requires a new set of interconnect layers and a new resulting BGA package. The new package requirement for every type of integrated circuit die requires even further expense and additional lead time—especially during prototyping operations and short run ASIC designs, the increase in both expense and lead time can markedly reduce competitiveness.

Therefore, a flexible package design capable of readily adapting to a large variety of integrated circuit sizes and types is desirable. Such a package would allow keeping a large inventory of a single package type available since virtually all types of integrated circuit dice would fit one universal interconnect device type.

### SUMMARY

The present invention is a universal interconnect device for mounting and interconnecting a semiconductor integrated circuit die in preparation for mounting to another substrate, such as a printed circuit board. In an exemplary embodiment, the device consists of a laminate substrate having a first surface upon which the integrated circuit die may be mounted. Underlying and surrounding the die mount area is a plurality of substantially concentric electrically-conductive paths. The paths include a plurality of short electrical traces (i.e., spanning less than one-fourth of a distance of one side of any of the plurality of concentric rings) and a plurality of long electrical traces (i.e., spanning about one-half of a distance of one side). Each of the plurality of electrically-conductive paths is electrically isolated from each other and formed on the first surface of the laminate substrate. At least one of the plurality of electrically-conductive paths is located near an outer periphery of the laminate substrate.

A plurality of vias is arranged to traverse the laminate substrate between the first and second surface and a plurality of bonding features is mounted on a second surface of the laminate substrate. Each of the plurality of bonding features is electrically isolated both from one another and from the plurality of substantially concentric electrically-conductive paths. The plurality of bonding features is electrically connectable to one or more of the plurality of substantially concentric electrically-conductive paths through the plurality of vias.

### BRIEF DESCRIPTION OF THE DRAWINGS

FIG. 1 shows a cross-sectional view of a prior art multi-layer ball grid array package.

FIG. 2A is a plan view of an exemplary embodiment of the present invention showing a bottom side of a configurable laminate substrate for mounting an integrated circuit.

FIG. 2B is a plan view of an exemplary embodiment of the present invention showing top view of the configurable laminate substrate of FIG. 2A and includes a plurality of mounting rings laid out essentially concentrically and providing for flexibility in mounting an integrated circuit die.

FIGS. 2C and 2D are plan views showing exemplary embodiments of inner layer power and ground planes of the configurable laminate substrate of FIG. 2A.

FIG. 3 is a cross-sectional view of the configurable laminate substrate of FIG. 2A.

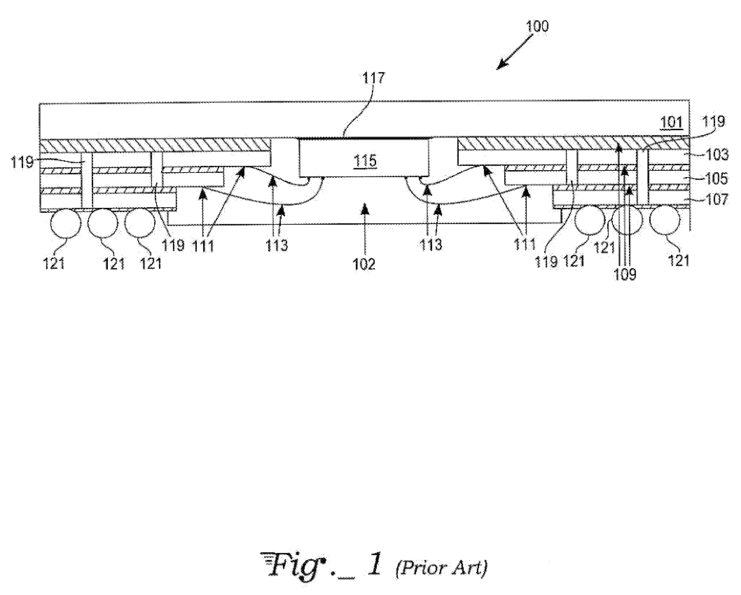

### DETAILED DESCRIPTION

The present invention is a universal interconnect device for mounting semiconductor integrated circuits. The device is configured with a plurality of concentric rings such that a wide variety of integrated circuit types and sizes may be mounted thereto without requiring a custom substrate for each integrated circuit device type or size. Various portions of the device may be interconnected with wire bonds or jumpers to appropriately connect an integrated circuit die to pins or pads. Further, the device is configured to work with standard board mounting schemes such as ball grid arrays (BGA) to which the wire bonds or jumpers may be interconnected.

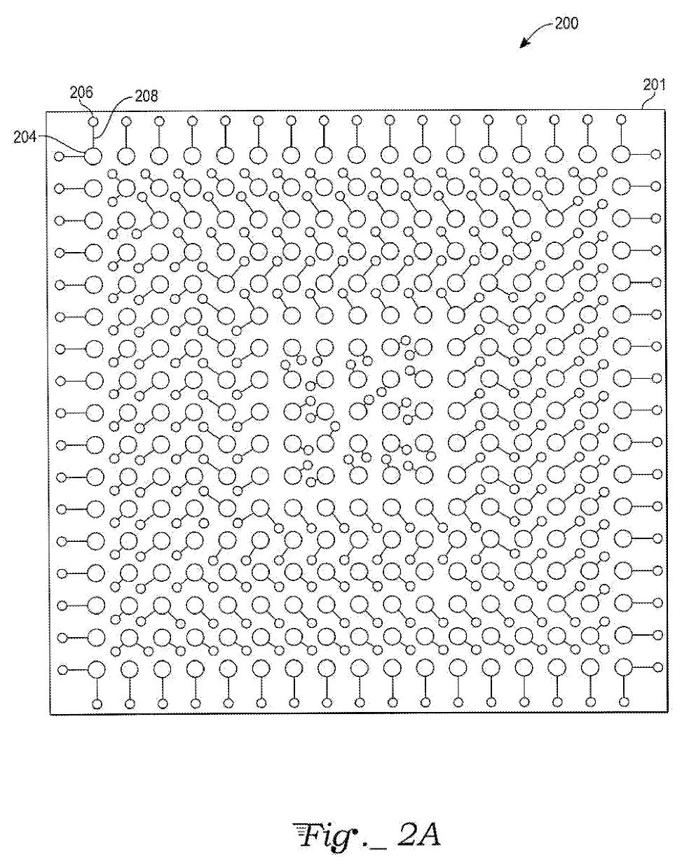

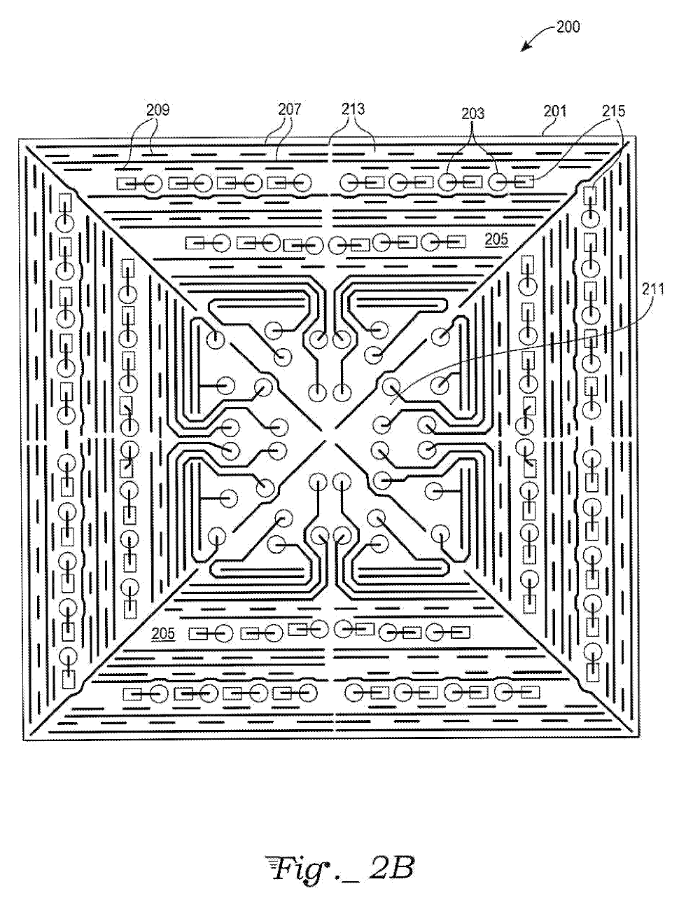

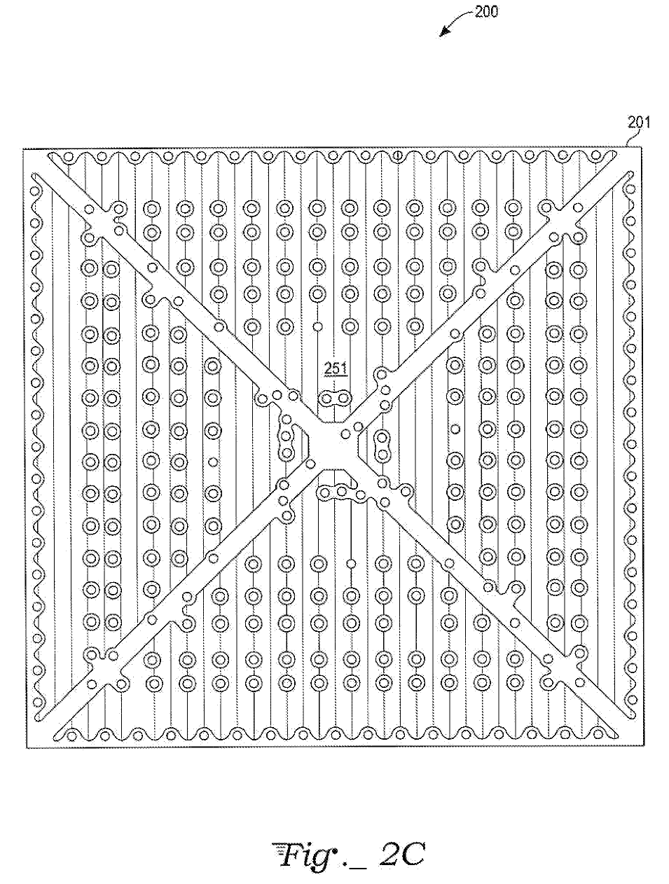

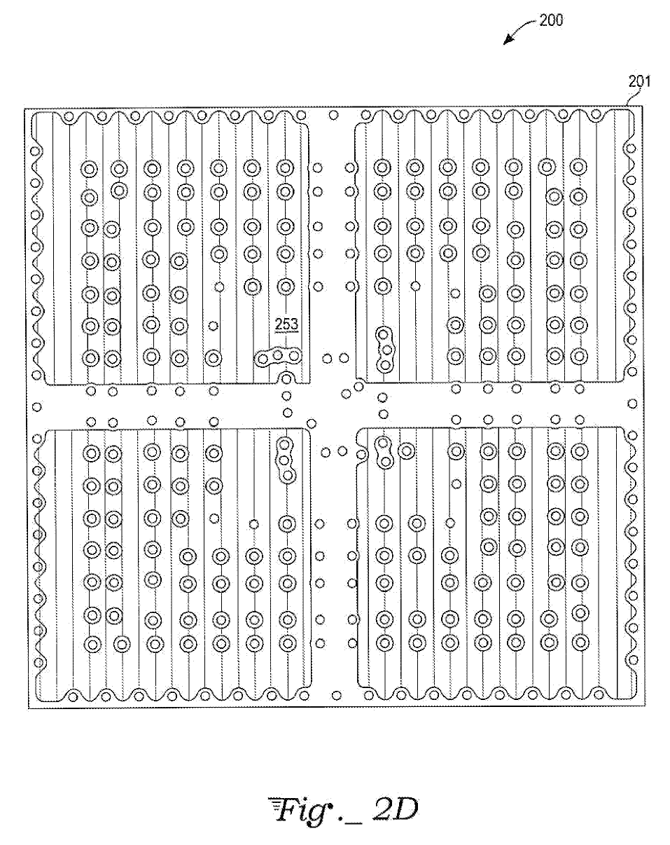

With reference to FIGS. 2A and 2B, an exemplary embodiment of a universal interconnect device 200 includes a laminate substrate 201. The laminate substrate 201 consists, on layer four 202 or bottom side (FIG. 2A), of an array of printed circuit board (PCB) bonding features 204. The bonding features 204 may include, for example, BGA solder balls, electroplated bumps, controlled collapse chip connection (“C4”) bump technology, or other types of PCB bonding features known in the art. Further, the bonding features 204 of the bottom side are arranged in a matrix pattern to conform to layout patterns typically found on integrated circuit dice. The pattern could be, for example, a common 0.8 mm pitch and include bonding pads covering an entire bottom area off the laminate substrate 201.

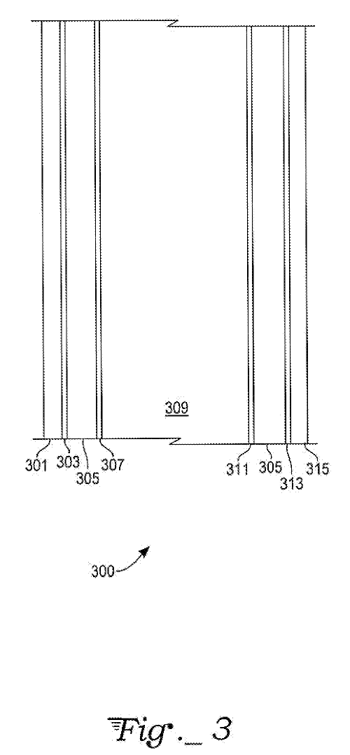

Each of the bonding features 204 is coupled to a plurality of vias 204 which routes power or signals from an integrated circuit mounted on layer one or front side (FIG. 2B) of the laminate substrate 201 to the back side. Each of the plurality of vias 206 is electrically coupled to the bonding features 202 by an electrical trace 208. Connecting vias 203 run through the laminate substrate 201 from the bottom side bonding features 204 to a topside/die attach layer 205. The connecting vias 203 may or may not align with the plurality of vias 206 on the bottom side of the laminate substrate 201 directly. Interlayer routing (described with regard to FIG. 3, infra) allows vias 203, 206 to be electrically connected as needed. If the vias 203, 206 are connected directly by a through hole, the through holes are plated using techniques known in the art.

With continued reference to FIG. 2B, long 207 and short 209 wirebond traces, in an exemplary embodiment, are largely arranged in a series of concentric ring-like structures surrounding a integrated circuit die mount area 211. In this embodiment, the long wirebond traces 207 are roughly one-half of a distance of any one of the concentric traces whereas the short wirebond traces are roughly one-fourth of the distance. A plurality of lengths within a given concentric ring as well as single lengths within the ring are also contemplated.

In a specific exemplary embodiment, a width of each of the wirebond traces 207, 209 is 75 μm with a 75 μm space between adjacent traces. Each of the wirebond traces 207, 209 may also be used as a bonding pad anywhere along its length. Additionally, rectangular bond, pads 215 are located in proximity to many of the connecting vias. As known to a skilled artisan, bond pads may have any shape, not necessarily rectangular. In this specific embodiment, the bond pads 215 are approximately 200 μm×300 μm in size. Further, each of the connecting vias 203 is coupled to adjacent layers (described infra) with a 150 μm drill diameter and each of the connecting vias 203 has a minimum 575 μm via-to-via pitch.

A plurality of breaks 213 in the wirebond traces 207, 209 allow jumpering with a wirebonder. Consequently, a wirebond connection can span or fan out away from an integrated circuit die (not shown) to any of the available traces 207, 209. The wirebond traces 207, 209 can subsequently be routed to the bonding features on the bottom side of the laminate substrate 201 so as to properly interconnect with any PCB configuration upon which the universal interconnect device 200 will eventually be mounted. Electrical interconnections between traces 207, 209 may be performed either prior to or after mounting of the integrated circuit die. The die may be attached with standard techniques, such as using a non-conductive epoxy layer or film. In a specific exemplary embodiment, the substrate is 10 mm by 10 mm in size. A larger version, 17 mm by 17 mm, allows for accommodating larger die sizes. A skilled artisan will recognise that other sizes and configurations of the substrate may readily be contemplated.

FIGS. 2C and 2D show, respectively, plan views of layers two 251 and three 253. The two layers 251, 253, provide power and ground planes and are described in more detail with regard to FIG. 3.

With reference to FIG. 3, an exemplary cross-sectional view 300 of the laminate, substrate 201 includes a layer one solder mask coating 301, a layer one copper foil (signal) layer 303, two epoxy layers 305, a layer two plane layer 307, a central core layer 303, a layer three plane layer 311, a layer four copper foil (signal) layer 313, and a layer four solder mask coating 315. In a specific exemplary embodiment, the layer one and layer four solder mask coating layers 301, 315 are each 19 μm to 38 μm in thickness. The layer one and layer four copper foil layers 303, 315 are each approximately 12 μm in thickness. The layer two and layer three plane layers 307, 311 (see FIGS. 2C and 2D) are each approximately 20 μm thick. The central core layer 309 and the two epoxy layers 305 may be comprised of BT Resin. BT Resin is a polymerization-type heat resistant thermosetting resin that includes two main components: B (Bismaleimide) and T (Triazine Resin). BT Resin was originally invented by Mitsubishi Gas Chemical Co., Ltd. In this specific exemplary embodiment, the cross-section of the laminate substrate 201 is 0.56±0.04 mm thick.

Substrates incorporating the present invention can be purchased in advance and held in inventory. The substrates can readily accommodate various sizes, densities, and patterns of various integrated circuit dice. The present invention depicted in the exemplary embodiment can readily be implemented with assembly equipment typically available at a semiconductor fabrication facility. Such equipment includes a wirebonder and epoxy dispense equipment. More complex routing includes jumpering over traces or underneath the integrated circuit die as required.

In the foregoing specification, the present invention has been described with reference to specific embodiments thereof. It will, however, be evident to a skilled artisan that various modifications and changes can be made thereto without departing from the broader spirit and scope of the invention as set forth in the appended claims. For example, skilled artisans will appreciate that various arrangements of laminate substrate size and shape may be used as well as various layouts and configurations of traces. The specification and drawings are, accordingly, to be regarded in an illustrative rather than a restrictive sense.

What is claimed is:

1. A universal interconnect device for mounting and interconnecting a semiconductor integrated circuit die, the device comprising:
a laminate substrate having a first surface upon which the integrated circuit die may be mounted;
a plurality of substantially concentric electrically-conductive paths, each of the plurality of electrically-conductive paths being electrically isolated from each other and formed oh the first surface of the laminate substrate, at least one of the plurality of electrically-conductive paths being located near an outer periphery of the laminate substrate;
a plurality of vias arranged to traverse the laminate substrate between the first surface of the laminate substrate and a second surface of the laminate substrate; and
a plurality of bonding features mounted on the second surface of the laminate substrate, each of the plurality of bonding features being electrically isolated from one another and from the plurality of substantially concentric electrically-conductive paths, the plurality of bonding features being electrically connectable to one or more of the plurality of substantially concentric electrically-conductive paths through the plurality of vias.

2. The universal interconnect device of claim 1 wherein each of plurality of substantially concentric electrically-conductive paths are electrically non-continuous and include non-conductive breaks in the path.

3. The universal interconnect device of claim 1 wherein the plurality of substantially concentric electrically-conductive paths includes a plurality of short electrical traces and a plurality of long electrical traces, the plurality of short electrical traces spanning less than one-fourth of a distance of one side of any of the plurality of concentric rings and the plurality of long paths spanning about one-half of a distance of one side of any of the plurality of concentric rings.

4. The universal interconnect device of claim 3 wherein the plurality of short traces and the plurality of long traces are contained in dissimilar electrically-conductive paths.

5. The universal interconnect device of claim 1 wherein the laminate substrate is about 10 mm square.

6. The universal interconnect device of claim 1 wherein the laminate substrate is about 17 mm square.

7. The universal interconnect device of claim 1 wherein each of the plurality of substantially concentric electrically-conductive paths are comprised substantially of aluminum.

8. The universal interconnect device of claim 1 wherein each of the plurality of substantially concentric electrically-conductive paths are comprised substantially of copper.

9. The universal interconnect device of claim 1 wherein the plurality of bonding features are comprised of a ball grid array.

10. The universal interconnect device of claim 1 wherein the plurality of bonding features are comprised of electroplated bumps.

11. The universal interconnect device of claim 1 wherein the plurality of bonding features are comprised of controlled collapse chip connections.

12. A universal interconnect device for mounting and interconnecting a semiconductor integrated circuit die, the device comprising:
a laminate substrate having a first surface upon which the integrated circuit die may be mounted;
a plurality of substantially concentric electrically-conductive paths including a plurality of short electrical traces and a plurality of long electrical traces, the plurality of short electrical traces spanning less than one-fourth of a distance of one side of any of the plurality of concentric rings and the plurality of long paths spanning about one-half of a distance of one side of any of the plurality of concentric rings, each of the plurality of electrically-conductive paths being electrically isolated from each other and formed on the first surface of the laminate substrate, at least one of the plurality of electrically-conductive paths being located near an outer periphery of the laminate substrate;
a plurality of vias arranged to traverse the laminate substrate between the first surface of the laminate substrate and a second surface of the laminate substrate; and
a plurality of bonding features mounted on the second surface of the laminate substrate, each of the plurality of bonding features being electrically isolated from one another and from the plurality of substantially concentric electrically-conductive paths, the plurality of bonding features being electrically connectable to one or more of the plurality of substantially concentric electrically-conductive paths through the plurality of vias.

13. The universal interconnect device of claim 12 wherein each of the plurality of substantially concentric electrically-conductive paths are comprised substantially of aluminum.

14. The universal interconnect device of claim 12 wherein each of the plurality of substantially concentric electrically-conductive paths are comprised substantially of copper.

15. The universal interconnect device of claim 12 wherein the laminate substrate is about 10 mm square.

16. The universal interconnect device of claim 12 wherein the laminate substrate is about 17 mm square.

17. The universal interconnect device of claim 12 wherein the plurality of bonding features are comprised of a ball grid array.

18. The universal interconnect device of claim 12 wherein the plurality of bonding features are comprised of electroplated bumps.

19. The universal interconnect device of claim 12 wherein the plurality of bonding features are comprised of controlled collapse chip connections.
